(19) United States
(12) Patent Application Publication
(10) Pub. No.: US 2025/0201749 A1
(43) Pub. Date: Jun. 19, 2025

(54) SEMICONDUCTOR PACKAGES

(71) Applicant: Samsung Electronics Co., Ltd., Suwon-si (KR)

(72) Inventors: Jiyoung Yoon, Suwon-si (KR); Jinyoung Kim, Suwon-si (KR); Okseon Yoon, Suwon-si (KR); Kiseok Kim, Suwon-si (KR); Jihye Shim, Suwon-si (KR)

(21) Appl. No.: 18/972,300

(22) Filed: Dec. 6, 2024

(30) Foreign Application Priority Data
Dec. 19, 2023 (KR) 10-2023-0186302

(51) Int. Cl. H01L 23/00

(52) U.S. Cl. CPC H01L 24/13; H01L 24/05; H01L 2224/0401; H01L 2224/13022; H01L 2224/13076; H01L 2224/13083; H01L 2224/13147; H01L 2224/13166; H01L 2224/13176; H01L 2224/13181

(57) ABSTRACT

A semiconductor package is provided. The semiconductor package includes a redistribution line that is arranged on a substrate and includes a first top surface portion, a redistribution insulating layer that is arranged on the substrate, covers the redistribution line, and includes an opening that exposes the first top surface portion of the redistribution line, an under-bump structure arranged within the opening of the redistribution insulating layer, the under-bump structure including an adhesive layer arranged on a sidewall of the opening, a seed layer arranged on the sidewall of the opening and on the first top surface portion of the redistribution line, and an under-bump metal layer arranged on the seed layer and filling the opening, and a solder layer arranged on the under-bump structure.

### CROSS-REFERENCE TO RELATED APPLICATION

This application is based on and claims priority under 35 U.S.C. § 119 to Korean Patent Application No. 10-2023-0186302, filed on Dec. 19, 2023, in the Korean Intellectual Property Office, the disclosure of which is incorporated by reference herein in its entirety.

### BACKGROUND

The invention relates to a semiconductor package, and more specifically, to a semiconductor package having an under-bump structure.

In response to the rapid development of the electronics industry and user demands, electronic devices are becoming more compact and lighter, and accordingly, high integration of semiconductor devices, which are key components of electronic devices, is required. For a highly integrated semiconductor chip with an increased number of input/output (I/O) connection terminals, a semiconductor package with connection reliability is being devised. For example, to prevent interference between connection terminals, a fan-out semiconductor package is being developed to increase the spacing between connection terminals.

### SUMMARY

Aspects of the invention provide a semiconductor package with improved reliability of a redistribution structure.

According to an aspect of the invention, there is provided a semiconductor package including a redistribution line arranged on a substrate and includes a top surface. The top surface includes a first top surface portion. The semiconductor package further includes a redistribution insulating layer arranged on the substrate, covering the redistribution line, and including an opening that exposes the first top surface portion of the redistribution line. The semiconductor package further includes an under-bump structure arranged within the opening of the redistribution insulating layer. The under-bump structure includes an adhesive layer arranged on a sidewall of the opening, a seed layer arranged on the sidewall of the opening and on the first top surface portion of the redistribution line, and an under-bump conductive layer arranged on the seed layer and filling the opening. The semiconductor package further includes a bump arranged on the under-bump structure. The seed layer includes a first portion arranged on the first top surface portion of the redistribution line, and the first portion is in contact with the first top surface portion of the redistribution line.

According to another aspect of the invention, there is provided a semiconductor package including a substrate and a redistribution structure arranged on a top surface of the substrate. The redistribution structure includes a redistribution line and a redistribution insulating layer arranged on the redistribution line. The semiconductor package further includes an under-bump structure arranged on the redistribution structure. The under-bump structure passes through the redistribution insulating layer and is on a top surface of the redistribution line. The semiconductor package further includes a bump arranged on the under-bump structure. The under-bump structure includes an under-bump conductive layer including a horizontal extension portion arranged at a vertical level higher than a top surface of the redistribution insulating layer with respect to the top surface of the substrate, and a via portion arranged at a vertical level lower than the top surface of the redistribution insulating layer and surrounded by the redistribution insulating layer. The under-bump structure further includes an adhesive layer arranged between a sidewall of the via portion and the redistribution insulating layer, and a seed layer between the sidewall of the via portion and the adhesive layer. The redistribution insulating layer includes an opening exposing the top surface of the redistribution line, and the seed layer includes a first portion arranged on the top surface of the redistribution line. The via portion of the seed layer is in contact with the top surface of the redistribution line.

According to another aspect of the invention, there is provided a semiconductor package including a substrate and a redistribution structure arranged on a top surface of the substrate. The redistribution structure includes a redistribution line and a redistribution insulating layer arranged on the redistribution line. The redistribution line includes a top surface, and the redistribution insulating layer includes an opening exposing the top surface. The semiconductor package further includes a passivation layer between the redistribution line and the redistribution insulating layer. The semiconductor package further includes an under-bump structure arranged on the redistribution structure. The under-bump structure includes an adhesive layer arranged on a sidewall of the opening of the redistribution insulating layer, a seed layer arranged on the sidewall of the opening of the redistribution insulating layer and on the top surface of the redistribution line, and an under-bump conductive layer arranged on the seed layer. The under-bump conductive layer includes a horizontal extension portion arranged at a vertical level higher than a top surface of the redistribution insulating layer with respect to the top surface of the substrate, and a via portion arranged at a vertical level lower than the top surface of the redistribution insulating layer and surrounded by the redistribution insulating layer. The semiconductor package further includes a bump arranged on the under-bump structure.

According to another aspect of the invention, there is provided a semiconductor package including a redistribution line arranged on a substrate and includes a top surface portion. The semiconductor package further includes a redistribution insulating layer arranged on the substrate, covering the redistribution line, and including a first opening that exposes the first top surface portion of the redistribution line. The semiconductor package further includes an adhesive layer arranged on a sidewall of the first opening. The semiconductor package further includes a seed layer arranged on the sidewall of the first opening and on the top surface portion of the redistribution line. The semiconductor package further includes an under-bump conductive layer arranged on the seed layer and filling the first opening. The semiconductor package further includes a bump arranged on the under-bump conductive layer. The adhesive layer includes a second opening, and the second opening exposes at least a portion of the top surface portion of the redistribution line.

### BRIEF DESCRIPTION OF THE DRAWINGS

Embodiments of the invention will be more clearly understood from the following detailed description taken in conjunction with the accompanying drawings in which:

FIG. 1 is a cross-sectional view illustrating a semiconductor package according to embodiments;

FIG. 2 is a cross-sectional view illustrating a semiconductor package according to embodiments;

FIG. 3 is a cross-sectional view illustrating a semiconductor package according to embodiments;

FIG. 4 is a cross-sectional view illustrating a semiconductor package according to embodiments;

FIG. 5 is a cross-sectional view illustrating a semiconductor package according to embodiments;

FIG. 6 is a cross-sectional view illustrating a semiconductor package according to embodiments;

FIG. 7 is a cross-sectional view illustrating a semiconductor package according to embodiments;

FIG. 8 is a cross-sectional view illustrating a semiconductor package according to embodiments;

FIG. 9 is a cross-sectional view illustrating a semiconductor package according to embodiments;

FIG. 10 is an enlarged view of a portion A of FIG. 9;

FIG. 11 is a cross-sectional view illustrating a semiconductor package according to embodiments;

FIGS. 12, 13, 14A, 14B, 14C, and 15 to 19 are schematic diagrams showing a method of manufacturing a semiconductor package, according to embodiments; and

FIGS. 20 to 24 are schematic diagrams illustrating a method of manufacturing a semiconductor package, according to embodiments.

### DETAILED DESCRIPTION OF THE EMBODIMENTS

Hereinafter, embodiments of the invention will be described in detail with reference to the accompanying drawings.

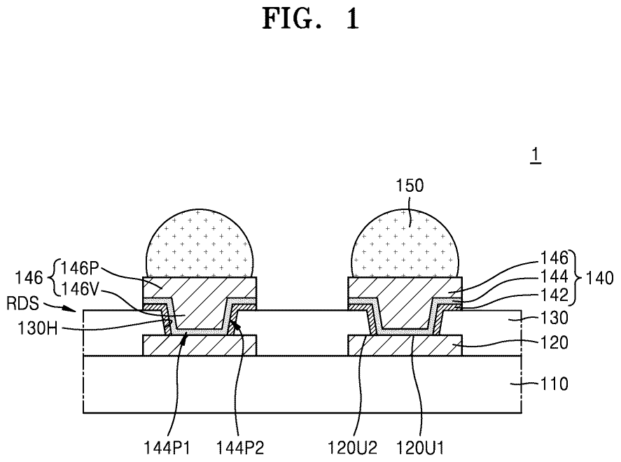

FIG. 1 is a cross-sectional view illustrating a semiconductor package 1 according to embodiments.

Referring to FIG. 1, a semiconductor package 1 may include a substrate 110, a redistribution line 120, a redistribution insulating layer 130, an under-bump structure 140, and a solder layer 150.

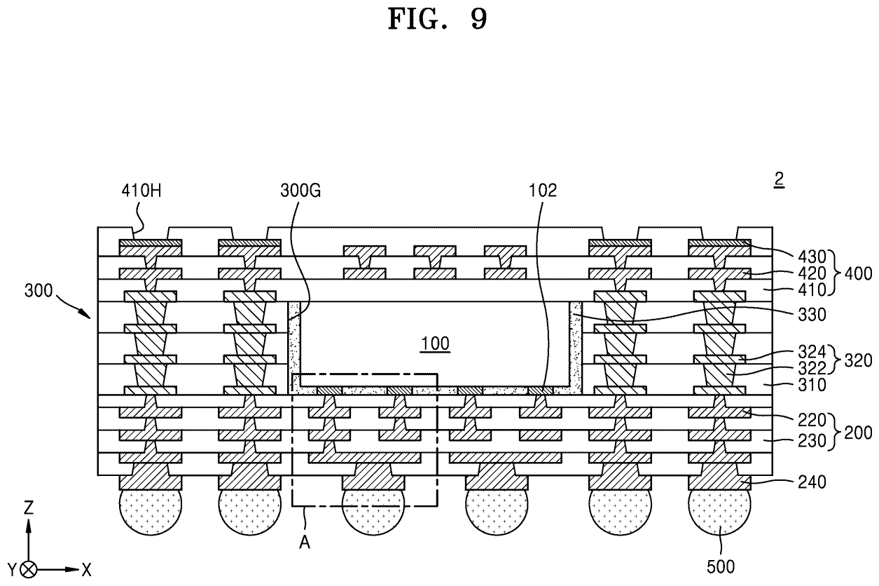

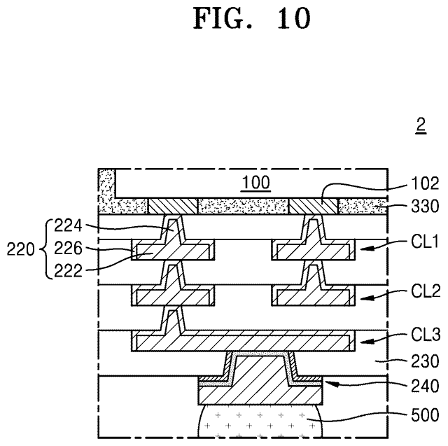

The substrate 110 may be a semiconductor substrate, a package substrate (e.g., a PCB board), an interposer or combination thereof. For example, in FIGS. 9 and 10, a semiconductor chip 100, a redistribution structure 200, a connection structure 300, a second redistribution structure 400, or combination thereof may be the substrate 110. The substrate 110 may include a semiconductor substrate including a semiconductor such as silicon, germanium, and silicon-germanium. A semiconductor device may be arranged on the substrate 110, and for example, the semiconductor device may include a plurality of semiconductor circuit components formed through a semiconductor manufacturing process. For example, a number of semiconductor circuit components including transistors, resistors, capacitors, conductive wirings, and the like may be arranged on the substrate 110. For example, the semiconductor device may include memory devices such as dynamic random-access memories (DRAMs) and flash memories, logic devices such as microcontrollers, analog devices, digital signal processor devices, system-on-chip devices, or combinations thereof.

The redistribution line 120 and the redistribution insulating layer 130 covering the redistribution line 120 may be arranged on the substrate 110. The redistribution line 120 and the redistribution insulating layer 130 may be portions of a redistribution structure RDS. The redistribution structure RDS may be formed by a redistribution process and may provide an electrical connection path to semiconductor devices arranged on the substrate 110. For example, the redistribution structure RDS may be part of a fan-out wafer level package or part of a fan-out panel level package.

The redistribution structure RDS may include a plurality of redistribution line segments arranged at different vertical levels, and the redistribution line 120 illustrated in FIG. 1 may correspond to the outermost (or uppermost) redistribution line segment of the plurality of redistribution line segments. The redistribution structure RDS may include a plurality of redistribution sub-insulating layers arranged at different vertical levels, and the redistribution insulating layer 130 illustrated in FIG. 1 may include the outermost (or uppermost) redistribution sub-insulating layer of the plurality of redistribution sub-insulating layers. In this case, redistribution line segments other than the outermost (or uppermost) redistribution line segment and redistribution sub-insulating layers other than the outermost (or uppermost) redistribution sub-insulating layer may be referred to as at least part of the substrate 110 in FIG. 1. In embodiments, the redistribution line 120 may be formed of, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof, but is not limited thereto. In some embodiments, the redistribution line 120 may include copper or a copper alloy. Although FIG. 1 shows that the redistribution line 120 includes a single layer, in embodiments, the redistribution line 120 may include a redistribution metal layer and a redistribution seed layer surrounding the bottom surface and sidewalls of the redistribution metal layer.

In embodiments, the redistribution insulating layer 130 may include or be formed of a photosensitive polymer. For example, the redistribution insulating layer 130 may be formed from a photo imageable dielectric (PID) or a photosensitive polyimide (PSPI), or may be formed of a build-up film such as Ajinomoto Build-up Film (ABF).

The redistribution insulating layer 130 may include an opening 130H, and a portion of the top surface of the redistribution line 120 may be exposed by a bottom portion of an opening 130H. Here, a portion of the top surface of the redistribution line 120 exposed by the bottom portion of the opening 130H is referred to as a first top surface portion 120U1, and the other portion of the top surface of the redistribution line 120 covered by the redistribution insulating layer 130 is referred to as a second top surface portion 120U2. For example, the first top surface portion 120U1 may not be covered by the redistribution insulating layer 130, and the second top surface portion 120U2 may be covered by the redistribution insulating layer 130 and may be in contact with the redistribution insulating layer 130.

In embodiments, as illustrated in FIG. 1, the first top surface portion 120U1 and the second top surface portion 120U2 of the redistribution line 120 may be arranged at the same vertical level, and for example, the first top surface portion 120U1 and the second top surface portion 120U2 may be substantially flat.

Terms such as “flat,” “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

The under-bump structure 140 electrically connected to the first top surface portion 120U1 of the redistribution line 120 may be arranged on the redistribution insulating layer 130. At least a portion of the under-bump structure 140 may be arranged in the opening 130H of the redistribution insulating layer 130, and at least a portion of the under-bump structure 140 may be arranged on the top surface of the redistribution insulating layer 130. The under-bump structure 140 may penetrate the redistribution insulating layer 130 and be arranged on the top surface of the redistribution line 120 (e.g., on the first top surface portion 120U1 of the redistribution line 120). The under-bump structure 140 may include an adhesive layer 142, a seed layer 144, and an under-bump metal layer 146 (also be described more generally as a “under-bump conductive layer”).

The adhesive layer 142 may be arranged on a sidewall of the opening 130H of the redistribution insulating layer 130. For example, the adhesive layer 142 may be arranged on the sidewall of the opening 130H of the redistribution insulating layer 130 but may not be arranged on the bottom portion of the opening 130H (e.g., on the first top surface portion 120U1 of the redistribution line 120). For example, the adhesive layer 142 may include or be formed of at least one of titanium, titanium nitride, tantalum, tantalum nitride, ruthenium, and ruthenium nitride.

The seed layer 144 may be arranged on the sidewall of the opening 130H of the redistribution insulating layer 130 and on the first top surface portion 120U1 of the redistribution line 120. The seed layer 144 may include a first portion 144P1 and a second portion 144P2, the first portion 144P1 may be arranged on the first top surface portion 120U1 of the redistribution line 120, and the second portion 144P2 may be arranged on the sidewalls of the opening 130H of the redistribution insulating layer 130 and on the top surface of the redistribution insulating layer 130. In embodiments, the seed layer 144 may include or be formed of copper or a copper alloy.

In embodiments, the first portion 144P1 of the seed layer 144 may be in contact with the first top surface portion 120U1 of the redistribution line 120. The adhesive layer 142 may not be arranged between the first portion 144P1 of the seed layer 144 and at least a portion of the first top surface portion 120U1 of the redistribution line 120.

In embodiments, the second portion 144P2 of the seed layer 144 may be arranged on the sidewall of the opening 130H of the redistribution insulating layer 130 and on the adhesive layer 142 on the top surface of the redistribution insulating layer 130. The adhesive layer 142 may be arranged between the second portion 144P2 and the redistribution insulating layer 130, and the second portion 144P2 may contact the adhesive layer 142 without contacting the redistribution insulating layer 130. The shape of the adhesive layer 142 may be a funnel-like shape with an opening (or a through-hole). The opening of the adhesive layer 142 may include an upper opening portion and a lower opening portion, and the lower opening portion exposes at least a portion of the top surface portion of the redistribution line 120. The area of the upper opening portion may have a greater area than that of the lower opening portion in a plan view. The area of the opening may be gradually decreased along a direction downward from the upper opening to the lower opening in a plan view.

The under-bump metal layer 146 may be arranged on the seed layer 144 and may fill the opening 130H. The under-bump metal layer 146 may include a horizontal extension portion 146P and a via portion 146V, the horizontal extension portion 146P may be arranged at a vertical level higher than the top surface of the redistribution insulating layer 130, and the via portion 146V may be arranged at a vertical level lower than the top surface of the redistribution insulating layer 130 and integrally connected to the horizontal extension portion 146P. The via portion 146V may be arranged in the opening 130H of the redistribution insulating layer 130 and may be surrounded by the redistribution insulating layer 130.

The via portion 146V may be surrounded by the seed layer 144 and the adhesive layer 142 in the opening 130H. For example, the second portion 144P2 of the seed layer 144 and the adhesive layer 142 may be sequentially arranged on the sidewall of the via portion 146V. For example, the adhesive layer 142 may be arranged between the sidewall of the via portion 146V and the redistribution insulating layer 130, and the second portion 144P2 of the seed layer 144 may be arranged between the sidewall of the via portion 146V and the adhesive layer 142.

The bottom surface of the via portion 146V may be in contact with the first portion 144P1 of the seed layer 144, and for example, the first portion 144P1 of the seed layer 144 may be arranged between the bottom surface of the via portion 146V and the first top surface portion 120U1 of the redistribution line 120. As illustrated in FIG. 1, the adhesive layer 142 may not be arranged between the bottom surface of the via portion 146V and at least a portion of the first top surface portion 120U1 of the redistribution line 120.

The solder layer 150 may be arranged on the horizontal extension portion 146P of the under-bump structure 140. As illustrated in FIG. 1, the solder layer 150 may have a spherical or ball shape. The solder layer 150 may include or be formed of tin (Sn), indium (In), bismuth (Bi), antimony (Sb), copper (Cu), silver (Ag), zinc (Zn), lead (Pb), and/or alloys thereof, but is not limited thereto. For example, the solder layer 150 may include or be formed of Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc. The solder layer 150 may also be described more generally as a “bump.” Each of the bumps 150 may be in the form of lands, balls, or pins, and may include a single layer or multiple layers.

In embodiments, the under-bump structure 140 may be formed by a process of forming the adhesive layer 142 on the inner wall of the opening 130H, removing a portion of the adhesive layer 142 arranged on the bottom portion of the opening 130H, and then forming the seed layer 144 and the under-bump metal layer 146.

In general, semiconductor packages according to comparative examples are manufactured by sequentially forming an adhesive layer and a seed layer on the inner wall of an opening and forming an under-bump metal layer on the seed layer. However, since redistribution lines and adhesive layers include different materials, the interfacial adhesive force between the redistribution line and the adhesive layer decreases or deteriorates over time, resulting in peeling or cracking between the redistribution line and the adhesive layer, between the adhesive layer and the redistribution insulating layer, and/or between the redistribution line and the redistribution insulating layer.

However, according to embodiments, the first portion 144P1 of the seed layer 144 is arranged on the top surface of the redistribution line 120, and the interfacial adhesive force between the redistribution line 120 and the seed layer 144 may be higher or better than the interfacial adhesive force between the redistribution line 120 and the adhesive layer 142. Accordingly, peeling or crack generation between the redistribution line 120 and the redistribution insulating layer 130 and/or between the under-bump structure 140 and the redistribution insulating layer 130 may be prevented or reduced, and the semiconductor package 1 may have excellent reliability. The adhesive layer 142 may enhance the interfacial adhesive force between the redistribution insulating layer 130 and the seed layer 144.

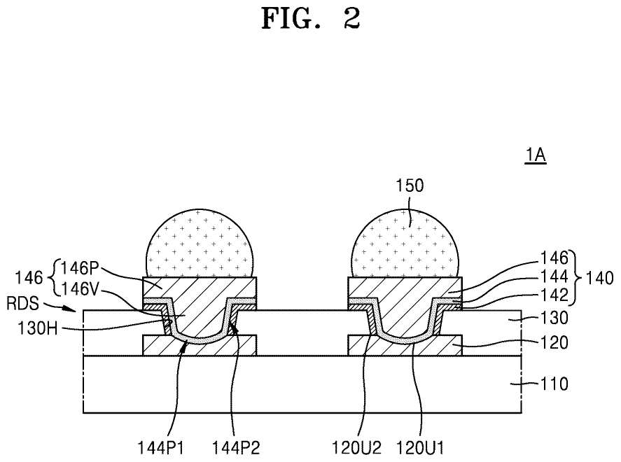

FIG. 2 is a cross-sectional view illustrating a semiconductor package 1A according to embodiments.

Referring to FIG. 2, the first top surface portion 120U1 of the redistribution line 120 may be arranged under the first portion 144P1 of the seed layer 144 and may contact the first portion 144P1 of the seed layer 144. The second top surface portion 120U2 of the redistribution line 120 may be in contact with the redistribution insulating layer 130. The first top surface portion 120U1 of the redistribution line 120 may be arranged at a lower vertical level than the second top surface portion 120U2 with respect to the top surface of the substrate 110. For example, the first top surface portion 120U1 of the redistribution line 120 may have a profile of a curved surface recessed downward. It will be understood that when an element A is referred to as being be arranged at “a lower vertical level than an element B with respect to” an element C, the element A is arranged lower than the element B and higher than the element C. It also will be understood that when an element A is referred to as being be arranged at “a higher vertical level than an element B with respect to” an element C, the element A is arranged higher than the elements B and C, and the element A is arranged higher than the element B.

In embodiments, the under-bump structure 140 may be formed by a process of forming the adhesive layer 142 on the inner wall of the opening 130H, removing a portion of the adhesive layer 142 arranged on the bottom portion of the opening 130H, and then forming the seed layer 144 and the under-bump metal layer 146. In embodiments, the process of removing a portion of the adhesive layer 142 may include a dry etching process. In embodiments, in the process of removing a portion of the adhesive layer 142, the first top surface portion 120U1 of the redistribution line 120, which is exposed at (or by) the bottom portion of the opening 130H, may be over-etched, and accordingly, the first top surface portion 120U1 of the redistribution line 120 may have a curved profile recessed downward.

According to embodiments, the contact area between the redistribution line 120 and the seed layer 144 may be relatively large, and the interfacial adhesive force between the redistribution line 120 and the seed layer 144 may be higher or better than the interfacial adhesive force between the redistribution line 120 and the adhesive layer 142. Accordingly, peeling or crack generation between the redistribution line 120 and the redistribution insulating layer 130 and/or between the under-bump structure 140 and the redistribution insulating layer 130 may be prevented or reduced, and the semiconductor package 1A may have excellent reliability.

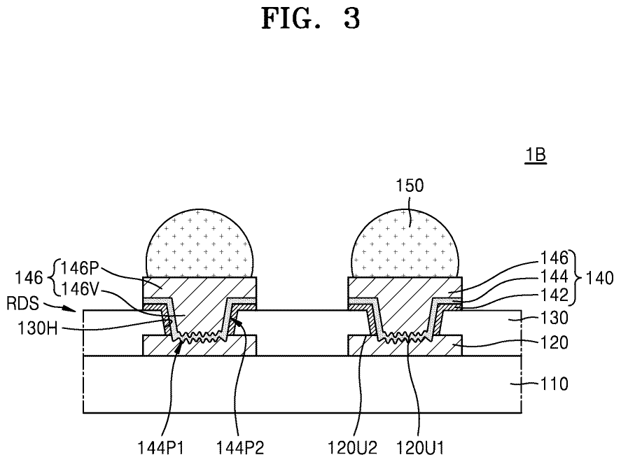

FIG. 3 is a cross-sectional view illustrating a semiconductor package 1B according to embodiments.

Referring to FIG. 3, the first top surface portion 120U1 of the redistribution line 120 may be arranged at a lower vertical level than the second top surface portion 120U2 with respect to the top surface of the substrate 110, and the first top surface portion 120U1 of the redistribution line 120 may have an uneven shape. For example, the first top surface portion 120U1 of the redistribution line 120 may have a surface roughness (Ra) or a root mean square roughness (RMS) of about 34 nanometers to about 200 nanometers. The Ra may be an arithmetic average of surface heights measured across a surface, e.g., an average of height across peaks and valleys. The RMS may be the square root of the average height deviations from the mean line/surface squared.

The first top surface portion 120U1 of the redistribution line 120 may be arranged under the first portion 144P1 of the seed layer 144 and may contact the first portion 144P1 of the seed layer 144. As the first top surface portion 120U1 of the redistribution line 120 has a relatively large surface roughness, the first portion 144P1 of the seed layer 144 in contact with the first top surface portion 120U1 of the redistribution line 120 may also have a relatively large surface roughness conforming to surface morphology of the first top surface portion 120U1 of the redistribution line 120.

In embodiments, the under-bump structure 140 may be formed by a process of forming the adhesive layer 142 on the inner wall of the opening 130H, removing a portion of the adhesive layer 142 arranged on the bottom portion of the opening 130H, and then forming the seed layer 144 and the under-bump metal layer 146. In embodiments, the process of removing a portion of the adhesive layer 142 may include a dry etching process.

In embodiments, the first top surface portion 120U1 of the redistribution line 120 exposed at (or by) the bottom portion of the opening 130H in the process of removing a portion of the adhesive layer 142 may be etched using a particular etchant (e.g., using an etchant including potassium peroxymonosulfate (KHSO₅) or sodium persulfate (Na₂S₂O₈)), so as to have a relatively large surface roughness, and thus the first top surface portion 120U1 of the redistribution line 120 may be formed to have an uneven shape.

According to embodiments, as the redistribution line 120 has a relatively large surface roughness, the contact area between the redistribution line 120 and the seed layer 144 may be relatively large, and the interfacial adhesive force between the redistribution line 120 and the seed layer 144 may be higher or better than the interfacial adhesive force between the redistribution line 120 and the adhesive layer 142. Accordingly, peeling or crack generation between the redistribution line 120 and the redistribution insulating layer 130 and/or between the under-bump structure 140 and the redistribution insulating layer 130 may be prevented or reduced, and the semiconductor package 1B may have excellent reliability.

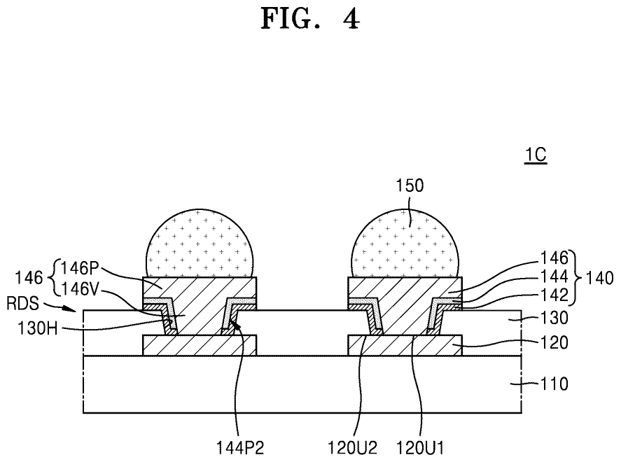

FIG. 4 is a cross-sectional view illustrating a semiconductor package 1C according to embodiments.

Referring to FIG. 4, the seed layer 144 may be arranged on the sidewall of the opening 130H of the redistribution insulating layer 130 and may not be arranged on the first top surface portion 120U1 of the redistribution line 120. The sidewalls of the under-bump metal layer 146 may be surrounded by the seed layer 144 and the adhesive layer 142, while the bottom surface of the under-bump metal layer 146 may be in contact with the first top surface portion 120U1 of the redistribution line 120.

In embodiments, the under-bump structure 140 may be formed by a process of sequentially forming the adhesive layer 142 and the seed layer 144 on the inner wall of the opening 130H, sequentially removing a portion of the seed layer 144 and a portion of the adhesive layer 142 arranged on the bottom portion of the opening 130H, and then forming the under-bump metal layer 146 in the opening 130H.

In FIG. 4, the first top surface portion 120U1 of the redistribution line 120 is shown to have a flat top surface profile, but unlike this, the first top surface portion 120U1 of the redistribution line 120 may have a downwardly recessed profile as described with reference to FIGS. 2 and 3, or the first top surface portion 120U1 of the redistribution line 120 may have an uneven shape.

In embodiments, the under-bump metal layer 146 may include or be formed of the same material as (or similar material to) the material of the redistribution line 120. According to embodiments, since the redistribution line 120 includes the same constituent material as the constituent material of the redistribution line 120, the under-bump metal layer 146 may have excellent interfacial adhesive force between the redistribution line 120 and the under-bump metal layer 146, and thus peeling or crack generation between the redistribution line 120 and the redistribution insulating layer 130 and/or the under-bump structure 140 and the redistribution insulating layer 130 may be prevented or reduced, and the semiconductor package 1C may have excellent reliability.

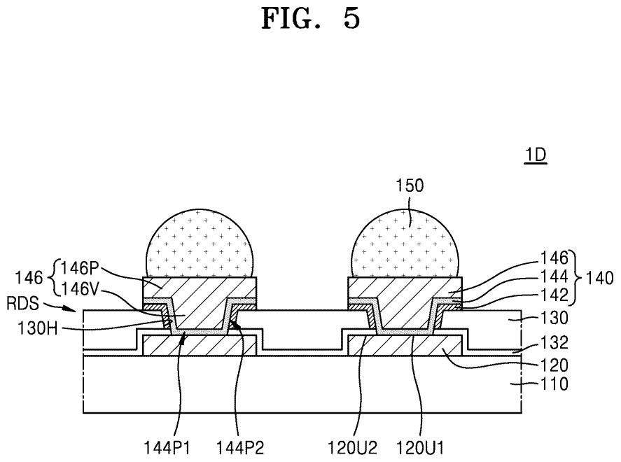

FIG. 5 is a cross-sectional view illustrating a semiconductor package 1D according to embodiments.

Referring to FIG. 5, the redistribution structure RDS may further include a passivation layer 132 covering a top surface and sidewalls of the redistribution line 120. In embodiments, the passivation layer 132 may be arranged between the redistribution insulating layer 130 and the redistribution line 120 to cover the top surface and sidewalls of the redistribution line 120 and extend onto the substrate 110.

In some embodiments, the redistribution structure RDS may include a plurality of redistribution line segments arranged at different vertical levels, and the redistribution line 120 illustrated in FIG. 5 may correspond to the outermost (or uppermost) redistribution line segment of the plurality of redistribution line segments. The redistribution structure RDS may include a plurality of redistribution sub-insulating layers arranged at different vertical levels, and the redistribution insulating layer 130 illustrated in FIG. 5 may include the outermost (or uppermost) redistribution sub-insulating layer of the plurality of redistribution sub-insulating layers. In this case, unlike the illustration in FIG. 5, the passivation layer 132 may cover the top surface and sidewalls of the outermost (or uppermost) redistribution line segment among the plurality of redistribution line segments and extend onto the second uppermost redistribution sub-insulating layer (now shown) arranged directly below the outermost (or uppermost) redistribution sub-insulating layer among the plurality of redistribution sub-insulating layers. In addition, the passivation layer 132 may be arranged between the uppermost redistribution sub-insulating layer and the second uppermost redistribution sub-insulating layer.

In embodiments, the passivation layer 132 may be arranged on the second top surface portion 120U2 of the redistribution line 120, and the second top surface portion 120U2 and the sidewalls of the redistribution line 120 may not be in contact with the redistribution insulating layer 130 by the passivation layer 132 therebetween. The passivation layer 132 may cover the top surface and sidewalls of the redistribution line 120, thereby preventing unwanted oxidation or damage to the copper metal constituting the redistribution line 120 in the process of applying, exposing, and developing a photoresist material for forming the redistribution insulating layer 130.

In embodiments, the passivation layer 132 may include or be formed of at least one of silicon oxide, silicon nitride, and silicon oxynitride. In embodiments, the passivation layer 132 may have a double layer structure, and the double layer structure may include or be formed of a double layer structure of a silicon oxide layer and a silicon nitride layer, a double layer structure of a silicon nitride layer and a silicon oxynitride layer, or a double layer structure of a silicon oxide layer and a silicon oxynitride layer. In embodiments, the passivation layer 132 may have a triple layer structure of a silicon oxide layer, a silicon nitride layer, and a silicon oxide layer. In other embodiments, the passivation layer 132 may include or be formed of an inorganic material other than the material described above.

In embodiments, the passivation layer 132 may have a thickness of about 50 nanometers to about 500 nanometers on the top surface of the substrate 110 in a vertical direction perpendicular to the top surface of the substrate 110. When the thickness of the passivation layer 132 is less than about 50 nm, it may be difficult to sufficiently prevent surface oxidation of the redistribution line 120 in the process of forming the redistribution insulating layer 130. When the thickness of the passivation layer 132 is greater than about 500 nm, cracks or peeling may occur between the redistribution insulating layer 130 and the passivation layer 132.

According to embodiments, the passivation layer 132 may prevent unwanted oxidation or damage of the copper metal included in the redistribution line 120 such that peeling or crack generation between the redistribution line 120 and the redistribution insulating layer 130 and/or between the under-bump structure 140 and the redistribution insulating layer 130 may be prevented or reduced, and the semiconductor package 1D may have excellent reliability.

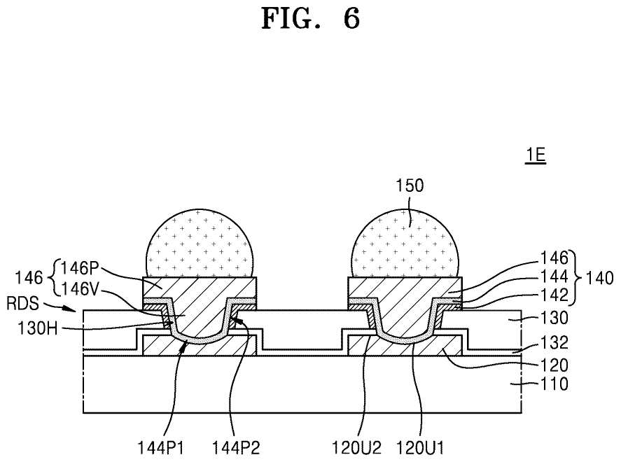

FIG. 6 is a cross-sectional view illustrating a semiconductor package 1E according to embodiments.

Referring to FIG. 6, the passivation layer 132 may be arranged on the second top surface portion 120U2 and the sidewalls of the redistribution line 120, and the first top surface portion 120U1 of the redistribution line 120 may be arranged at a lower vertical level than the second top surface portion 120U2 with respect to the top surface of the substrate 110. For example, the first top surface portion 120U1 of the redistribution line 120 may have a profile of a curved surface recessed downward.

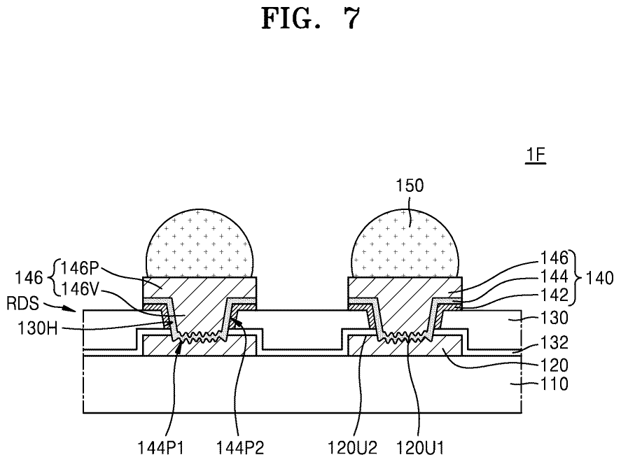

FIG. 7 is a cross-sectional view illustrating a semiconductor package 1F according to embodiments.

Referring to FIG. 7, the passivation layer 132 may be arranged on the second top surface portion 120U2 and the sidewalls of the redistribution line 120, and the first top surface portion 120U1 of the redistribution line 120 may have an uneven shape. For example, the first top surface portion 120U1 of the redistribution line 120 may have a surface roughness or a root mean square roughness of about 34 nanometers to about 200 nanometers.

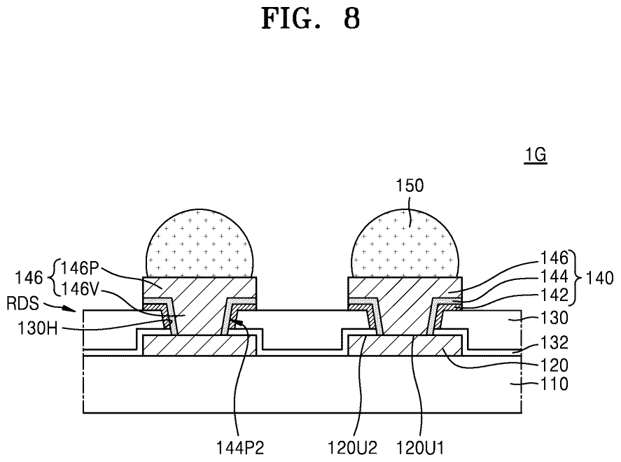

FIG. 8 is a cross-sectional view illustrating a semiconductor package 1G according to embodiments.

Referring to FIG. 8, the passivation layer 132 may be arranged on the second top surface portion 120U2 and the sidewalls of the redistribution line 120, and the seed layer 144 may be arranged on the sidewalls of the opening 130H of the redistribution insulating layer 130 and may not be arranged on the first top surface portion 120U1 of the redistribution line 120. The sidewalls of the under-bump metal layer 146 may be surrounded by the seed layer 144 and the adhesive layer 142, while the bottom surface of the under-bump metal layer 146 may be in contact with the first top surface portion 120U1 of the redistribution line 120.

FIG. 9 is a cross-sectional view illustrating a semiconductor package 2 according to embodiments. FIG. 10 is an enlarged view of a portion A of FIG. 9.

Referring to FIGS. 9 and 10, the semiconductor package 2 may have a fan-out panel level package structure. The semiconductor package 2 may include a semiconductor chip 100, a first redistribution structure 200, a connection structure 300, and a second redistribution structure 400. The semiconductor chip 100 may be arranged on the first redistribution structure 200, the connection structure 300 may be arranged on the first redistribution structure 200 to surround the semiconductor chip 100, and the second redistribution structure 400 may be arranged on the semiconductor chip 100 and the connection structure 300. The connection structure 300 may electrically connect the first redistribution structure 200 and the second redistribution structure 400 with each other.

In embodiments, the first redistribution structure 200 and the second redistribution structure 400 may be formed by a redistribution process. In example embodiments, the semiconductor package 2 may be formed in a chip-first manner in which the connection structure 300 and the semiconductor chip 100 are first formed and then the first redistribution structure 200 and the second redistribution structure 400 are formed.

The first redistribution structure 200 may include a plurality of first redistribution patterns 220 and a first redistribution insulating layer 230. The first redistribution insulating layer 230 may be arranged to surround the plurality of first redistribution patterns 220. In some embodiments, the first redistribution structure 200 may include the plurality of first redistribution insulating layers 230 stacked one after another.

In embodiments, the first redistribution insulating layer 230 may include or be formed of a photosensitive polymer. For example, the first redistribution insulating layer 230 may be formed from a PID or a PSPI, or may be formed of a build-up film such as ABF.

The plurality of first redistribution patterns 220 may include a plurality of first redistribution line patterns 222, a plurality of first redistribution vias 224, and a plurality of first redistribution seed layers 226. The plurality of first redistribution patterns 220 may be, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof, but is not limited thereto. In some embodiments, the first redistribution line pattern 222 and the first redistribution via 224 may include the same material, and the first redistribution seed layer 226 may include a material different from each of the first redistribution line pattern 222 and the first redistribution via 224. In embodiments, the first redistribution line pattern 222 and the first redistribution via 224 may include or be formed of copper or a copper alloy, and the first redistribution seed layer 226 may include or be formed of titanium or titanium nitride.

The plurality of first redistribution vias 224 may pass through at least one first redistribution insulating layer 230 to be connected to and in contact with some of the plurality of first redistribution line patterns 222, respectively. In some embodiments, the plurality of first redistribution vias 224 may have a tapered shape extending from a lower side to an upper side with a narrowing horizontal width. For example, the plurality of first redistribution vias 224 may have a horizontal width widening in a plan view in a direction away from at least one semiconductor chip 100.

In some embodiments, at least some of the plurality of first redistribution line patterns 222 may be formed together with some of the plurality of first redistribution vias 224 to be integrally connected with each other. For example, the first redistribution line pattern 222 and the first redistribution via 224 in contact with the top surface of the first redistribution line pattern 222. The first redistribution via 224 extending from the top surface of the first redistribution line pattern 222, may be formed together to be integrally connected with each other. For example, each of the plurality of first redistribution vias 224 may have a horizontal width narrowing in a plan view in a direction away from a portion of first redistribution line pattern 222. The first redistribution seed layer 226 may cover the first redistribution line pattern 222 and the first redistribution via 224 integrally formed with each other.

In embodiments, the plurality of first redistribution patterns 220 may include a plurality of first conductive lines CL1 arranged at a first vertical level, a plurality of second conductive lines CL2 arranged at a second vertical level lower than the plurality of first conductive lines CL1, and a plurality of third conductive lines CL3 arranged at a third vertical level lower than the plurality of second conductive lines CL2.

Here, the first vertical level may indicate a level lower than the top surface of the first redistribution structure 200. In addition, the second vertical level may indicate a lower level than the top surface of the first redistribution structure 200, and the vertical distance from the semiconductor chip 100 to the second vertical level may be greater than the vertical distance from the semiconductor chip 100 to the first vertical level. In addition, the third vertical level may indicate a lower level than the top surface of the first redistribution structure 200, and the vertical distance from the semiconductor chip 100 to the third vertical level may be greater than the vertical distance from the semiconductor chip 100 to the second vertical level.

A plurality of under-bump structures 240 may be arranged on the bottom surface of the first redistribution structure 200. The plurality of under-bump structures 240 may include any one of the under-bump structures 140 described with reference to FIGS. 1 to 9. A plurality of external connection terminals 500 may be attached to the plurality of under-bump structures 240, respectively. The plurality of external connection terminals 500 may connect the semiconductor package 2 to the outside. Each of the plurality of external connection terminals 500 may include a solder ball or a solder bump.

The semiconductor chip 100 may be attached onto the first redistribution structure 200. The semiconductor chip 100 may be mounted on the first redistribution structure 200 in a flip chip manner. The semiconductor chip 100 may be electrically connected to the redistribution pattern 220 of the first redistribution structure 200 through a lower chip pad 102.

In embodiments, the semiconductor chip 100 may be a memory chip or a logic chip. The memory chip may be, for example, a volatile memory chip such as dynamic random access memory (DRAM) or static random access memory (SRAM), or a nonvolatile memory chip such as NAND flash memory, phase-change random access memory (PRAM), magnetoresistive random access memory (MRAM), ferroelectric random access memory (FeRAM), or resistive random access memory (RRAM). In addition, the logic chip may be, for example, a microprocessor, an analog device, or a digital signal processor.

The connection structure 300 may have a mounting space 300G in which the semiconductor chip 100 is arranged and may include a base layer 310 and a plurality of connection vias 320. The plurality of connection vias 320 may penetrate the base layer 310. The connection structure 300 may be a printed circuit board (PCB), a ceramic substrate, a package manufacturing wafer, or an interposer. The connection structure 300 may include two or more stacked base layers 310 but may include a single base layer 310 in some embodiments. For example, the connection structure 300 may be a multi-layer printed circuit board.

The base layer 310 may include at least one material selected from phenol resin, epoxy resin, and polyimide. For example, the base layer 310 may include at least one material selected from frame retardant 4 (FR4), tetrafunctional epoxy, polyphenylene ether, epoxy/polyphenylene oxide, bismaleimide triazine (BT), Thermount, Cyanate ester, polyimide and liquid crystal polymer.

In embodiments, the plurality of connection vias 320 may include electrolytically deposited (ED) copper foil, rolled-annealed (RA) copper foil, stainless steel foil, aluminum foil, ultra-thin copper foil, sputtered copper, copper alloys, etc. Each of the plurality of connection vias 320 may include a via portion 322 penetrating the base layer 310, and a connection pattern portion 324 arranged on the top surface of the base layer 310 and integrally connected to the via portion 322.

The semiconductor package 2 may further include a filling insulating layer 330 filling the mounting space 300G. The filling insulating layer 330 may fill a space between the semiconductor chip 100 arranged in the mounting space 300G and the base layer 310. For example, the filling insulating layer 330 may include thermosetting resin such as epoxy resin, thermoplastic resin such as polyimide, or resin including a reinforcing material such as an inorganic filler, specifically ABF, FR-4, BT, etc. Alternatively, the filling insulating layer 330 may be formed from a molding material such as epoxy molding compound (EMC) or a photosensitive material such as photoimagable encapsulant (PIE). In embodiments, a portion of the filling insulating layer 330 may include an insulating material such as a silicon oxide layer, a silicon nitride layer, or a silicon oxynitride layer.

The second redistribution structure 400 may include a second redistribution insulating layer 410 and a plurality of second redistribution patterns 420. The plurality of second redistribution patterns 420 may include a plurality of second redistribution patterns, a plurality of second redistribution vias, and a plurality of second redistribution seed layers. The second redistribution insulating layer 410 and the plurality of second redistribution patterns 420 included in the second redistribution structure 400 are generally similar to the plurality of first redistribution patterns 220 and the first redistribution insulating layer 230 included in the first redistribution structure 200, and redundant description may be omitted.

The second redistribution structure 400 may further include a plurality of top surface connection pads 430 arranged on the top surface of the second redistribution structure 400. The plurality of top surface connection pads 430 may include nickel (Ni) or gold (Au). The second redistribution insulating layer 410 includes an opening 410H at an upper side of the second redistribution insulating layer 410, and the top surface of each of the plurality of top surface connection pads 430 may be exposed by the opening 410H.

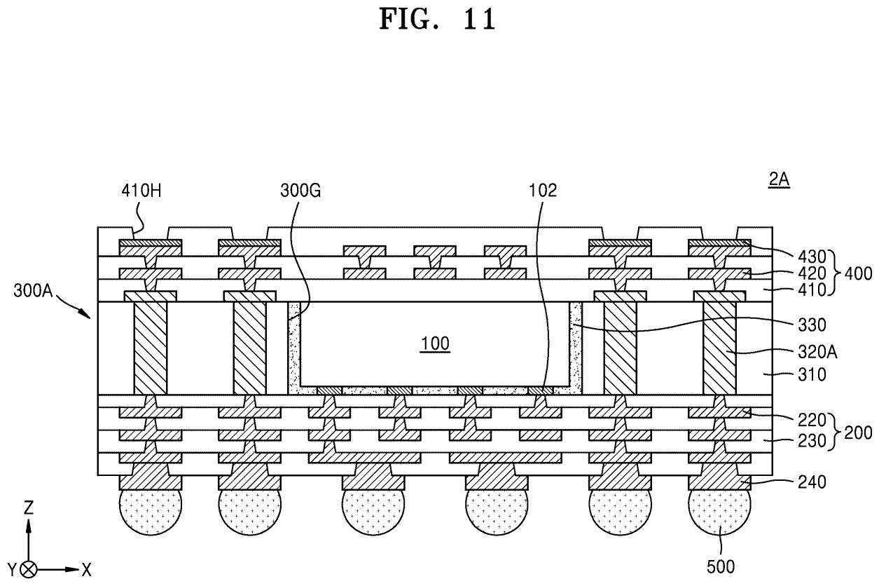

FIG. 11 is a cross-sectional view illustrating a semiconductor package 2A according to embodiments. The various portions of the semiconductor package 2A may be similar or identical to the portions of the semiconductor package 2 shown in FIG. 9, and thus the same reference numbers may be used and redundant description may be omitted.

Referring to FIG. 11, the semiconductor package 2A may have a fan-out wafer level package structure. The semiconductor package 2A may include a semiconductor chip 100, a first redistribution structure 200, a connection structure 300A, and a second redistribution structure 400. The semiconductor chip 100 may be arranged on the first redistribution structure 200, the connection structure 300A may be arranged on the first redistribution structure 200 to surround the semiconductor chip 100, and the second redistribution structure 400 may be arranged on the semiconductor chip 100 and the connection structure 300A. The connection structure 300A may electrically connect the first redistribution structure 200 and the second redistribution structure 400 with each other.

In embodiments, the first redistribution structure 200 and the second redistribution structure 400 may be formed by a redistribution process. In example embodiments, the semiconductor package 2A may be formed in a chip-first manner in which the connection structure 300A and the semiconductor chip 100 are first formed and then the first redistribution structure 200 and the second redistribution structure 400 are formed.

The connection structure 300A may have a mounting space 300G in which the semiconductor chip 100 is arranged and may include a base layer 310 and a plurality of connection vias 320A. The plurality of connection vias 320A may penetrate the base layer 310 from the top surface of the base layer 310 to the bottom surface thereof. The plurality of connection vias 320A may include copper or a copper alloy. A plurality of under-bump structures 240 may be arranged on the bottom surface of the first redistribution structure 200. The plurality of under-bump structures 240 may include any one of the under-bump structures 140 described with reference to FIGS. 1 to 9.

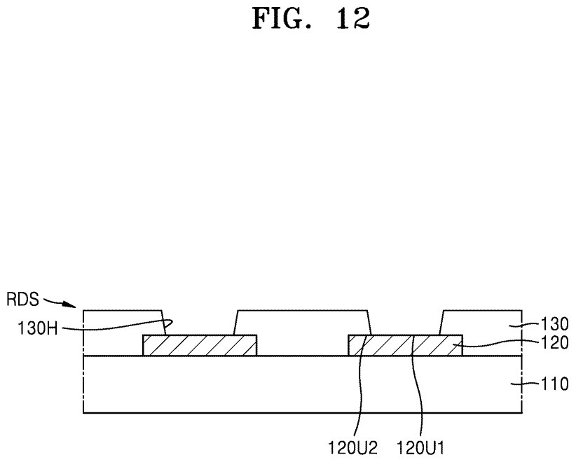

FIGS. 12, 13, 14A, 14B, 14C, and 15 to 19 are schematic diagrams showing a method of manufacturing a semiconductor package 1, according to embodiments.

Referring to FIG. 12, the redistribution line 120 and the redistribution insulating layer 130 covering the redistribution line 120 may be formed on the substrate 110. The redistribution insulating layer 130 may include an opening 130H.

In embodiments, the redistribution insulating layer 130 may include a photosensitive polymer. For example, the redistribution insulating layer 130 may be formed from a PID or PSPI, or may be formed of a build-up film such as ABF. In embodiments, the redistribution insulating layer 130 including the opening 130H may be formed by sequentially performing application or coating, curing, and developing processes of a photoresist material.

The first top surface portion 120U1 of the redistribution line 120 may be exposed at (or by) the bottom portion of the opening 130H, and the second top surface portion 120U2 of the redistribution line 120 may be covered by the redistribution insulating layer 130 and may be in contact with the redistribution insulating layer 130.

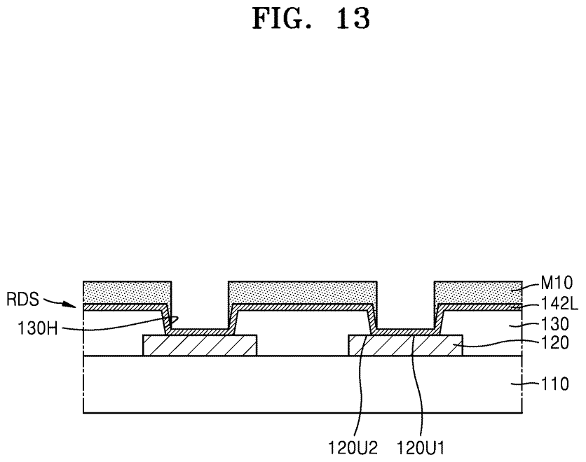

Referring to FIG. 13, a preliminary adhesive layer 142L may be formed on the redistribution insulation layer 130. The preliminary adhesive layer 142L may be conformally arranged on the inner wall of the opening 130H of the redistribution insulating layer 130, and a portion of the preliminary adhesive layer 142L may be arranged on the first top surface portion 120U1 of the redistribution line 120 at the bottom portion of the opening 130H of the redistribution insulating layer 130.

In embodiments, the preliminary adhesive layer 142L may include or be formed of at least one of titanium, titanium nitride, tantalum, tantalum nitride, ruthenium, and ruthenium nitride. The preliminary adhesive layer 142L may be formed by using at least one of a physical vapor deposition process, a chemical vapor deposition process, and an atomic layer deposition process.

Thereafter, a first mask M10 may be arranged on the preliminary adhesive layer 142L. The first mask M10 may expose at least a portion of the opening 130H of the redistribution insulating layer 130.

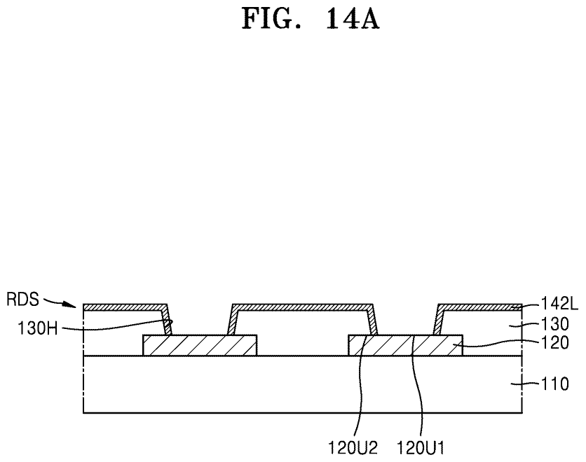

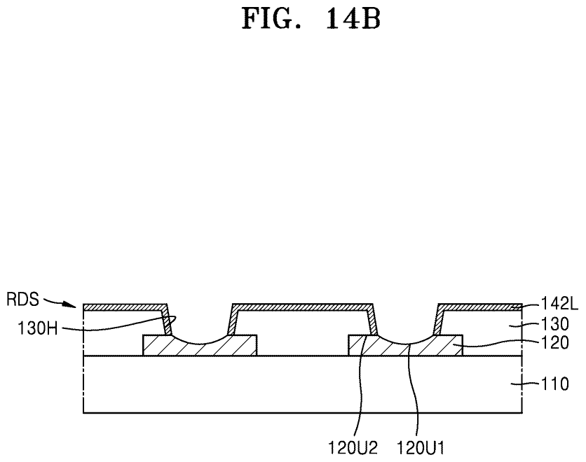

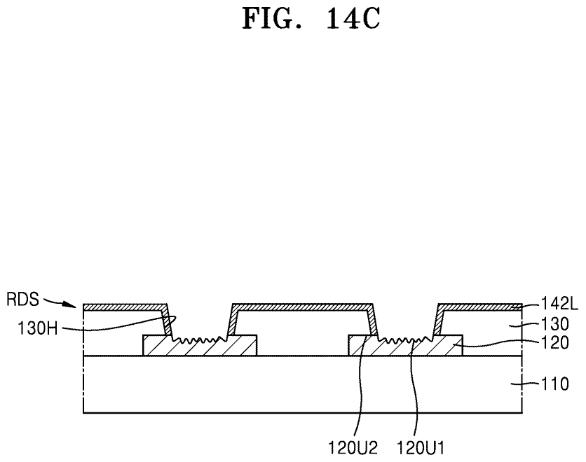

Referring to FIG. 14A, a portion of the preliminary adhesive layer 142L on the first top surface portion 120U1 of the redistribution line 120 may be removed using the first mask M10 as an etching mask. By removing a portion of the preliminary adhesive layer 142L on the first top surface portion 120U1 of the redistribution line 120, the first top surface portion 120U1 of the redistribution line 120 may be exposed by the bottom portion of the opening 130H.

In embodiments, the process of removing a portion of the preliminary adhesive layer 142L may include a dry etching process. In the process of removing a portion of the preliminary adhesive layer 142L, the first top surface portion 120U1 of the redistribution line 120 exposed at (or by) the bottom portion of the opening 130H may have a substantially flat top surface level.

FIGS. 14B and 14C illustrate various shapes of the top surface of the redistribution line 120 formed after the process of removing a portion of the preliminary adhesive layer 142L.

Referring to FIG. 14B, in the process of removing a portion of the preliminary adhesive layer 142L, the first top surface portion 120U1 of the redistribution line 120 exposed at (or by) the bottom portion of the opening 130H may be over-etched, and accordingly, the first top surface portion 120U1 of the redistribution line 120 may have a curved profile recessed downward. In this case, the semiconductor package 1A described with reference to FIG. 2 may be manufactured.

Referring to FIG. 14C, the first top surface portion 120U1 of the redistribution line 120 exposed at (or by) the bottom portion of the opening 130H in the process of removing a portion of the preliminary adhesive layer 142L may be etched using a particular etchant (e.g., using an etchant including potassium peroxymonosulfate (KHSOs) or sodium persulfate (Na₂S₂O₈)), so as to have a relatively large surface roughness, and thus the first top surface portion 120U1 of the redistribution line 120 may be formed to have an uneven shape. For example, the first top surface portion 120U1 of the redistribution line 120 may have a surface roughness or a root mean square roughness of about 34 nanometers to about 200 nanometers. In this case, the semiconductor package 1B described with reference to FIG. 3 may be manufactured.

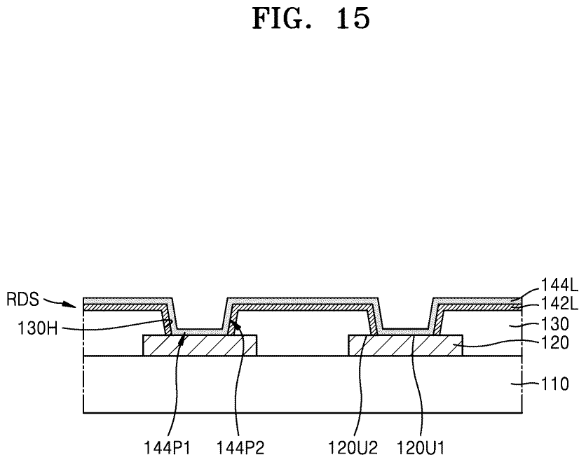

Referring to FIG. 15, a preliminary seed layer 144L may be formed on the preliminary adhesive layer 142L. The preliminary seed layer 144L may be conformally formed on a portion of the preliminary seed layer 144L arranged on the sidewalls of the opening 130H and on the first top surface portion 120U1 of the redistribution line 120.

In embodiments, the preliminary seed layer 144L may include or be formed of copper or a copper alloy. The preliminary seed layer 144L may be formed by using at least one of a physical vapor deposition process, a chemical vapor deposition process, and an atomic layer deposition process.

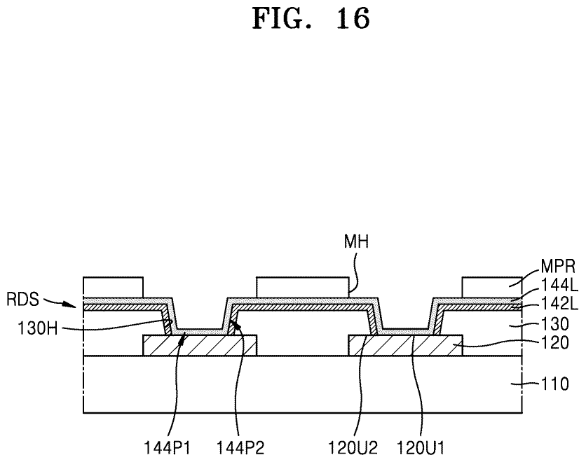

Referring to FIG. 16, a mask pattern MPR may be formed on the preliminary seed layer 144L.

In example embodiments, the mask pattern MPR may be formed using a photoresist material. The mask pattern MPR may include an opening MH, and the opening MH of the mask pattern MPR may be arranged at a position vertically overlapping the opening 130H of the redistribution insulating layer 130 to expose the opening 130H of the redistribution insulating layer 130 without covering the opening 130H.

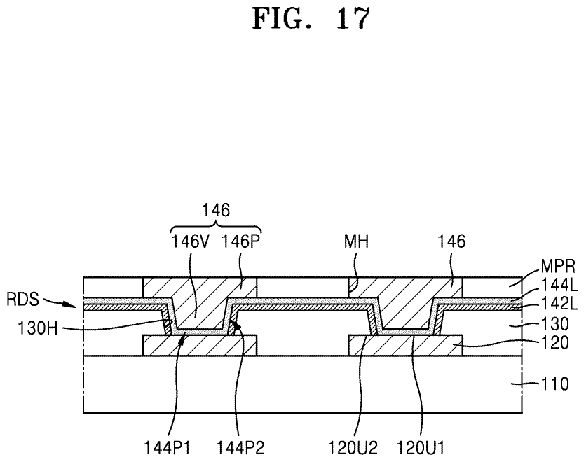

Referring to FIG. 17, the under-bump metal layer 146 may be formed in the opening 130H of the redistribution insulating layer 130 and in the opening MH of the mask pattern MPR.

In embodiments, the under-bump metal layer 146 may be formed using a plating process including an electroplating or electroless plating process. In the plating process for forming the under-bump metal layer 146, the preliminary seed layer 144L may be used as a seed material.

In embodiments, the under-bump metal layer 146 may include a horizontal extension portion 146P and a via portion 146V. The horizontal extension portion 146P may be a portion of the under-bump metal layer 146 arranged in the opening MH of the mask pattern MPR. The horizontal extension portion 146P may be arranged at a vertical level higher than the top surface of the redistribution insulating layer 130. The via portion 146V may be a portion of the under-bump metal layer 146 arranged in the opening 130H of the redistribution insulating layer 130. The via portion 146V may be arranged at a vertical level lower than the top surface of the redistribution insulating layer 130 and may be integrally connected to the horizontal extension portion 146P.

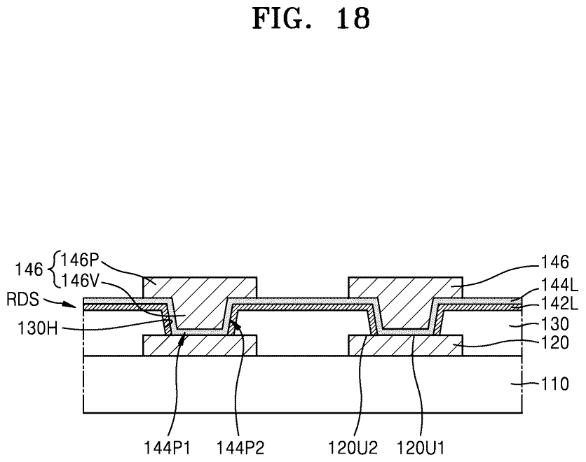

Referring to FIG. 18, the mask pattern MPR may be removed.

As the mask pattern MPR is removed, a surface of the preliminary seed layer 144L not covered by the under-bump metal layer 146 may be exposed.

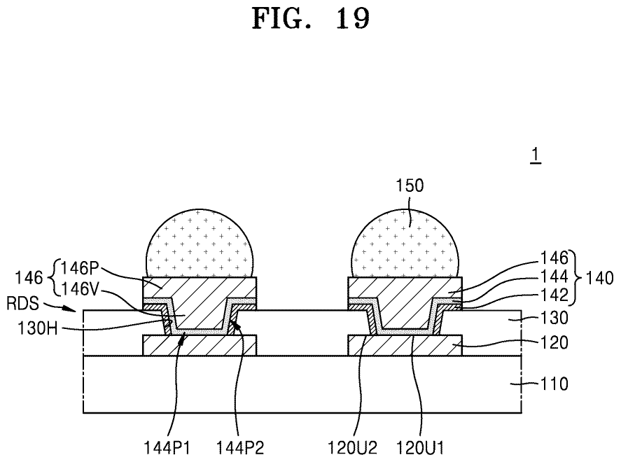

Referring to FIG. 19, a portion of the preliminary seed layer 144L (see FIG. 18) and a portion of the preliminary adhesive layer 142L (see FIG. 18) arranged on the top surface of the redistribution insulating layer 130 may be removed to form a seed layer 144 and an adhesive layer 142.

In embodiments, a process of removing a portion of the preliminary seed layer 144L and a portion of the preliminary adhesive layer 142L may be a wet etching process. In the wet etching process, a portion of the preliminary seed layer 144L, which is covered by the horizontal extension portion 146P of the under-bump metal layer 146 and arranged on the inner wall of the opening 130H, may remain without being removed, and a portion of the preliminary adhesive layer 142L, which is covered by the horizontal extension portion 146P of the under-bump metal layer 146 and arranged on the sidewalls of the opening 130H, may remain without being removed. The remaining preliminary seed layer 144L and the remaining preliminary adhesive layer 142L may be referred to as the seed layer 144 and the adhesive layer 142, respectively.

Thereafter, the solder layer 150 may be formed on the top surface of the under-bump metal layer 146.

The semiconductor package 1 may be formed by the processes described above.

In general, semiconductor packages according to comparative examples are manufactured by sequentially forming an adhesive layer and a seed layer on the inner wall of an opening and forming an under-bump metal layer on the seed layer. However, since redistribution lines and adhesive layers include different materials, the interfacial adhesive force between the redistribution line and the adhesive layer decreases or deteriorates over time, resulting in peeling or cracking between the redistribution line and the adhesive layer, between the adhesive layer and the redistribution insulating layer, and/or between the redistribution line and the redistribution insulating layer.

However, according to embodiments, a portion of the preliminary adhesive layer 142L covering the top surface of the redistribution line 120 may be removed by an etching process, and accordingly, the interfacial adhesive force between the redistribution line 120 and the seed layer 144 formed of the same material may be relatively large. Accordingly, peeling or crack generation between the redistribution line 120 and the redistribution insulating layer 130 and/or between the under-bump structure 140 and the redistribution insulating layer 130 may be prevented or reduced, and the semiconductor package 1 may have excellent reliability.

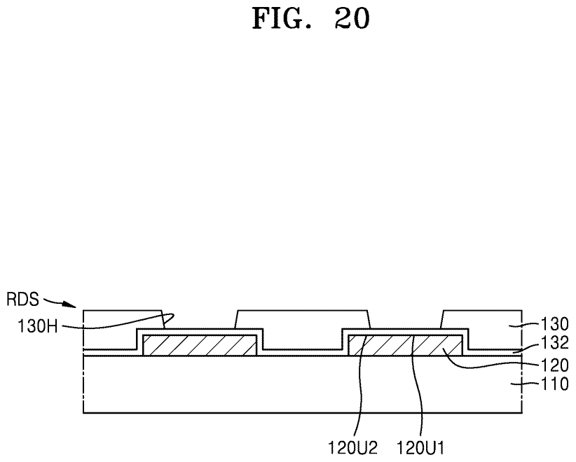

FIGS. 20 to 24 are schematic diagrams illustrating a method of manufacturing a semiconductor package 1D, according to embodiments.

Referring to FIG. 20, the redistribution line 120 may be formed on the substrate 110, and the passivation layer 132 may be formed on the redistribution line 120.

In embodiments, the passivation layer 132 may include or be formed of silicon oxide, silicon nitride, silicon oxynitride, or an inorganic material other than the material described above. The passivation layer 132 may be formed by using at least one of a physical vapor deposition process, a chemical vapor deposition process, and an atomic layer lamination process. The passivation layer 132 may have a thickness of about 50 nanometers to about 500 nanometers in a vertical direction perpendicular to the top surface of the substrate 110.

Thereafter, the redistribution insulating layer 130 may be formed on the passivation layer 132. The redistribution insulating layer 130 may include the opening 130H. In embodiments, the redistribution insulating layer 130 including the opening 130H may be formed by sequentially performing application or coating, curing, and developing processes of a photoresist material.

As the passivation layer 132 is formed on the redistribution line 120, the first top surface portion 120U1 of the redistribution line 120 may not be exposed at (or by) the bottom portion of the opening 130H, and the top surface of the passivation layer 132 may be exposed. For example, both the first top surface portion 120U1 and the second top surface portion 120U2 of the redistribution line 120 may be covered by the passivation layer 132 and may not be exposed during the process of forming the redistribution insulating layer 130 (e.g., during the process of applying, curing, and developing the photoresist material).

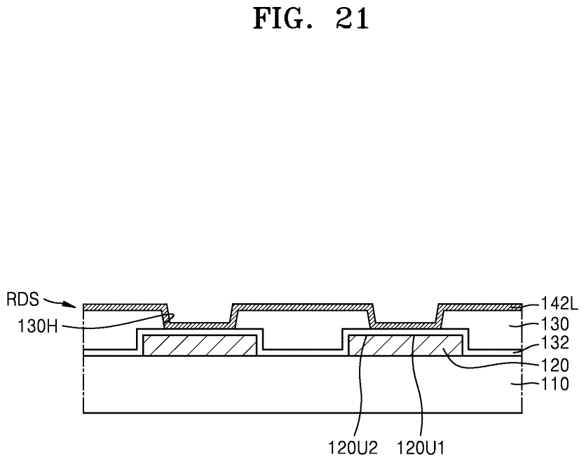

Referring to FIG. 21, a preliminary adhesive layer 142L may be formed on the redistribution insulation layer 130. The preliminary adhesive layer 142L may be conformally arranged on the inner wall of the opening 130H of the redistribution insulating layer 130, and a portion of the preliminary adhesive layer 142L may be arranged on the top surface of the passivation layer 132 at the bottom portion of the opening 130H of the redistribution insulating layer 130.

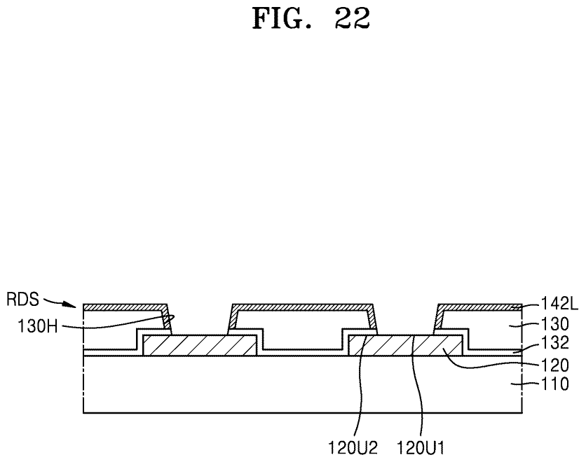

Referring to FIG. 22, a portion of the preliminary adhesive layer 142L arranged at the bottom portion of the opening 130H and a portion of the passivation layer 132 may be removed. By removing a portion of the preliminary adhesive layer 142L arranged at the bottom of the opening 130H and a portion of the passivation layer 132, the first top surface portion 120U1 of the redistribution line 120 may be exposed at (or by) the bottom portion of the opening 130H.

In embodiments, as described with reference to FIGS. 14B and 14C, the first top surface portion 120U1 of the redistribution line 120 may have a curved profile recessed downward by adjusting the etching process for removing a portion of the preliminary adhesive layer 142L, or the first top surface portion 120U1 of the redistribution line 120 may be formed to have an uneven shape.

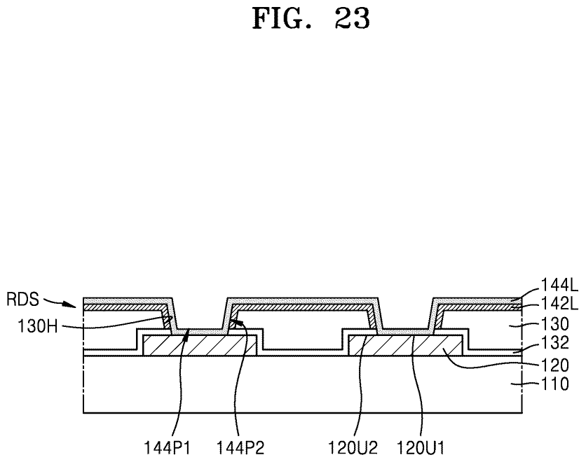

Referring to FIG. 23, a preliminary seed layer 144L may be formed on the preliminary adhesive layer 142L. The preliminary seed layer 144L may be conformally formed on a portion of the preliminary seed layer 144L arranged on the sidewalls of the opening 130H and on the first top surface portion 120U1 of the redistribution line 120.

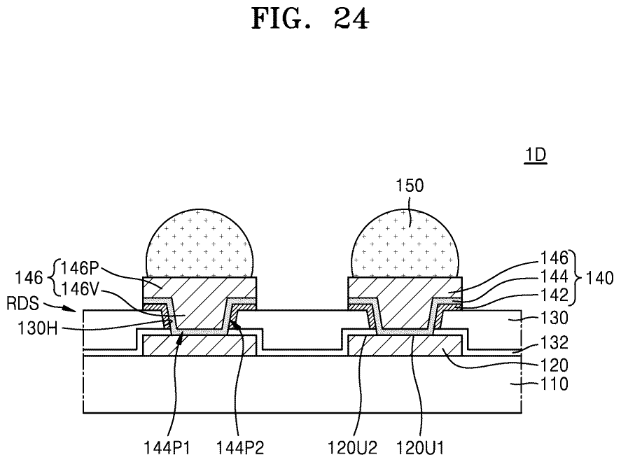

Referring to FIG. 24, a mask pattern MPR (see FIG. 17) may be formed on the preliminary seed layer 144L (see FIG. 23), and an under-bump metal layer 146 may be formed in the opening 130H of the redistribution insulating layer 130 and the opening MH (see FIG. 17) of the mask pattern MPR.

Thereafter, the mask pattern MPR may be removed, and a portion of the preliminary seed layer 144L and the preliminary adhesive layer 142L (see FIG. 23) arranged on the top surface of the redistribution insulating layer 130 may be removed to form a seed layer 144 and an adhesive layer 142.

Thereafter, the solder layer 150 may be formed on the top surface of the under-bump metal layer 146.

The semiconductor package 1D may be manufactured by the processes described above.

According to embodiments, the passivation layer 132 may cover the top surface and sidewalls of the redistribution line 120, thereby preventing unwanted oxidation or damage of the copper metal included in the redistribution line 120 in the process of forming the redistribution insulating layer 130. Accordingly, peeling or crack generation between the redistribution line 120 and the redistribution insulating layer 130 and/or between the under-bump structure 140 and the redistribution insulating layer 130 may be prevented or reduced, and the semiconductor package 1D may have excellent reliability.

While the invention has been particularly shown and described with reference to embodiments thereof, it will be understood that various changes in form and details may be made therein without departing from the spirit and scope of the following claims.

As used herein, spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It should be appreciated that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly. For example, the features of FIG. 1 are rotated 90 degrees, and incorporated into FIG. 10)

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

1. A semiconductor package comprising:
a redistribution line arranged on a substrate and includes a top surface, wherein the top surface includes a first top surface portion;
a redistribution insulating layer arranged on the substrate, the redistribution insulating layer covering the redistribution line and including an opening that exposes the first top surface portion of the redistribution line;
an under-bump structure arranged within the opening of the redistribution insulating layer, the under-bump structure including an adhesive layer arranged on a sidewall of the opening, a seed layer arranged on the sidewall of the opening and on the first top surface portion of the redistribution line, and an under-bump conductive layer arranged on the seed layer and filling the opening; and
a bump arranged on the under-bump structure,
wherein the seed layer includes a first portion arranged on the first top surface portion of the redistribution line, and the first portion is in contact with the first top surface portion of the redistribution line.

2. The semiconductor package of claim 1, wherein the seed layer includes a second portion arranged on the sidewall of the opening of the redistribution insulating layer, and the second portion is in contact with the adhesive layer.

3. The semiconductor package of claim 2, wherein the adhesive layer is not arranged between the first portion of the seed layer and at least a portion of the first top surface portion of the redistribution line.

4. The semiconductor package of claim 3, wherein the first portion of the seed layer is arranged between the first top surface portion of the redistribution line and a bottom surface of the under-bump conductive layer.

5. The semiconductor package of claim 1, wherein
the adhesive layer comprises at least one of titanium, titanium nitride, tantalum, tantalum nitride, ruthenium, and ruthenium nitride, and
the seed layer comprises copper or a copper alloy.

6. The semiconductor package of claim 1, wherein the first top surface portion of the redistribution line is flat.

7. The semiconductor package of claim 1, wherein
the top surface of the redistribution line further includes a second top surface portion,
the redistribution insulating layer is in contact with the second top surface portion of the redistribution line, and
the first top surface portion of the redistribution line is arranged at a lower level than the second top surface portion of the redistribution line with respect to a top surface of the substrate.

8. The semiconductor package of claim 1, wherein the first top surface portion of the redistribution line has an uneven shape.

9. The semiconductor package of claim 8, wherein the first top surface portion of the redistribution line has a surface roughness of about 34 nanometers to about 200 nanometers.

10. The semiconductor package of claim 1, further comprising a passivation layer covering at least a portion of a top surface and a side surface of the redistribution line.

11. The semiconductor package of claim 10, wherein
the top surface of the redistribution line further includes a second top surface portion,
the passivation layer is in contact with the second top surface portion of the redistribution line, and
the passivation layer is arranged between the redistribution line and the redistribution insulating layer.

12. The semiconductor package of claim 10, wherein the passivation layer comprises at least one of silicon oxide, silicon oxynitride, and silicon nitride.

13. A semiconductor package comprising:
a substrate;
a redistribution structure arranged on a top surface of the substrate, the redistribution structure including a redistribution line and a redistribution insulating layer arranged on the redistribution line;
an under-bump structure arranged on the redistribution structure, the under-bump structure passing through the redistribution insulating layer and being on a top surface of the redistribution line; and
a bump arranged on the under-bump structure, wherein
the under-bump structure comprises:
an under-bump conductive layer including a horizontal extension portion arranged at a vertical level higher than a top surface of the redistribution insulating layer with respect to the top surface of the substrate, and a via portion arranged at a vertical level lower than the top surface of the redistribution insulating layer and surrounded by the redistribution insulating layer;
an adhesive layer arranged between a sidewall of the via portion and the redistribution insulating layer; and
a seed layer between the sidewall of the via portion and the adhesive layer,
wherein the redistribution insulating layer includes an opening exposing the top surface of the redistribution line, and the seed layer includes a first portion arranged on the top surface of the redistribution line, and
wherein the via portion of the seed layer is in contact with the top surface of the redistribution line.

14. The semiconductor package of claim 13, wherein the adhesive layer is not arranged between a bottom surface of the via portion and at least a portion of the top surface of the redistribution line.

15. The semiconductor package of claim 13, wherein the seed layer includes a second portion arranged on the sidewall of the opening of the redistribution insulating layer.

16. The semiconductor package of claim 15, wherein the second portion of the seed layer is in contact with the adhesive layer.

17. The semiconductor package of claim 16, wherein the first portion of the seed layer is arranged between the top surface of the redistribution line and a bottom surface of the via portion.

18. The semiconductor package of claim 13, wherein
the adhesive layer comprises at least one of titanium, titanium nitride, tantalum, tantalum nitride, ruthenium, and ruthenium nitride, and
the seed layer comprises copper or a copper alloy.

19. The semiconductor package of claim 13, further comprising a passivation layer covering the top surface and a side surface of the redistribution line and arranged between the redistribution line and the redistribution insulating layer.

20. A semiconductor package comprising:
a substrate;
a redistribution structure arranged on a top surface of the substrate, the redistribution structure including a redistribution line and a redistribution insulating layer arranged on the redistribution line, wherein the redistribution line includes a top surface, and the redistribution insulating layer includes an opening exposing the top surface;
a passivation layer between the redistribution line and the redistribution insulating layer;
an under-bump structure arranged on the redistribution structure, the under-bump structure including an adhesive layer arranged on a sidewall of the opening of the redistribution insulating layer, a seed layer arranged on the sidewall of the opening of the redistribution insulating layer and on the top surface of the redistribution line, and an under-bump conductive layer arranged on the seed layer, the under-bump conductive layer including a horizontal extension portion arranged at a vertical level higher than a top surface of the redistribution insulating layer with respect to the top surface of the substrate, and a via portion arranged at a vertical level lower than the top surface of the redistribution insulating layer and surrounded by the redistribution insulating layer; and
a bump arranged on the under-bump structure.

21. (canceled)
